(19) United States
(12) Patent Application Publication
(10) Pub. No.: US 2017/0117495 A1
(43) Pub. Date: Apr. 27, 2017

(54) HYBRID ORGANIC/INORGANIC EUTECTIC SOLAR CELL

(71) Applicant: Solar-Tectic. LLC, Briarcliff Manor, NY (US)

(72) Inventor: Ashok Chaudhari, Briarcliff Manor, NY (US)

(73) Assignee: Solar-Tectic LLC, Briarcliff Manor, NY (US)

(21) Appl. No.: 15/402,744

(22) Filed: Jan. 10, 2017

(51) Int. Cl. H01L 51/42; H01L 51/52; H01L 51/50; H01G 9/20

(52) U.S. Cl. CPC H01L 51/4213; H01G 9/2004; H01L 51/5296; H01L 51/50; H01L 2031/0344

(57) ABSTRACT

A method and device for improving junctions in an organic, polymer, thin-film semiconductor device, and for facilitating the formation of a Schottky barrier between a polymer film and silicide film.

This application is a Continuation-in-part of U.S. patent application Ser. No. 15/138,774 filed Apr. 26, 2016, entitled “Hybrid Organic/Inorganic Eutectic Solar Cell,” which is a Divisional of U.S. patent application Ser. No. 14/571,800 filed Dec. 16, 2014, entitled “Hybrid Organic/Inorganic Eutectic Solar Cell,” and claims priority to U.S. Provisional Patent Application Ser. No. 61/919,985 filed Dec. 23, 2013, entitled “Eutectic Hybrid Organic/Inorganic Solar Cell”, all of which are hereby incorporated by reference in their entirety.

### FIELD OF THE INVENTION

The present invention is related to photovoltaics, particularly to producing a hybrid solar cell from organic and inorganic material. It is also related to display technology, such as organic light emitting transistors (OLETs) and organic light emitting diodes (OLEDs).

### BACKGROUND OF THE INVENTION

Hybrid solar cells are designed to exploit the unique interfacial electronic properties at the organic-inorganic boundary. This class of devices is rooted in nanostructured TiO2 or ZnO integrated with conjugated polymers (P3HT), but is rapidly expanding to include many other organic and inorganic materials including single and polycrystalline silicon (42^{nd} IEEE PV Specialists Conference 2015), for example silicon films on flexible polymer substrates or polymer buffered substrates.

A polymer is a large molecule, or macromolecule, composed of many repeated subunits. Because of their broad range of properties, both synthetic and natural polymers play an essential and ubiquitous role in everyday life. Polymers range from familiar synthetic plastics such as polystyrene to natural biopolymers such as DNA and proteins that are fundamental to biological structure and function. Polymers, both natural and synthetic, are created via polymerization of many small molecules, known as monomers. Their consequently large molecular mass relative to small molecule compounds produces unique physical properties, including toughness, viscoelasticity, and a tendency to form glasses and semi-crystalline structures rather than crystals.

Hybrid photovoltaic devices have a potential for not only low-cost by roll-to-roll processing but also for scalable solar power conversion. Recently there has been a growing interest in hybrid solar cells. Hybrid solar cells need, however, increased efficiencies and stability over time before commercialization is feasible. In comparison to the 2.4% of the CdSe-PPV system, silicon photodevices have power conversion efficiencies greater than 20%. It is therefore desirable to leverage the unique electronic and optical properties and functionality afforded by organic and inorganic materials, and those which utilize quantum confined nanostructures to enhance charge transport and fine-tune the spectral sensitivity range (42^{nd} IEEE PV Specialists Conference 2015).

Currently there are three types of hybrid solar cells: 1) polymer-nanoparticle composite, 2) carbon nanotubes, 3) dye-sensitized. Recent progress in materials science, however, now makes possible the production of a fourth, entirely new, hybrid solar cell which combines the benefits of a polymer with crystalline silicon and does so at a temperature that allows for material depositions on inexpensive substrates such as soda-lime glass.

U.S. Patent Application Publication 2009/0297774 (P. Chaudhari et al.) discloses a low temperature silicon deposition technique which allows for fabrication using organic materials as substrates.

U.S. Pat. No. 7,691,731 (Bet and Kar) discloses a low temperature silicon deposition technique on soft polymer substrates for a hybrid organic/inorganic solar cell. The process involves providing an aqueous solution medium including a plurality of semiconductor nanoparticles dispersed therein having a median size less than 10 nm, and applying the solution medium to at least one region of a substrate to be coated. The substrate has a melting or softening point of <200° C. The solution medium is evaporated and the region is laser irradiated for fusing the nanoparticles followed by annealing to obtain a continuous film having a recrystallized microstructure.

According to Bet and Kar, recent advances in physical vapor deposition (PVD) chemical vapor deposition (CVD) techniques and the use of excimer laser annealing (ELA) and solid phase annealing (SPA) have reduced the processing temperatures in thin film microelectronics considerably, thus promoting the use of inexpensive lightweight polymer substrates. However, existing silicon film preparation methods produce amorphous, or randomly aligned microcrystalline or polycrystalline Si films containing high densities of intrinsic microstructural defects which limit the utility of such films for high quality microelectronic applications. Deposition of near-single crystal or single crystal Si films on polymer substrates is a step toward achieving high quality flexible microelectronics. However, the non-crystalline nature of polymer makes it very difficult to employ a number of existing vapor-liquid and solid phase epitaxial growth processes because such processes rely on the crystalline character of the substrates. Secondly, the low melting or softening temperature of polymers makes it impractical to utilize the steady-state directional solidification processes, such as Zone melting recrystallization of Si films on SiO2 using a CW laser, a focused lamp, an electron beam or a graphite strip heater, previously developed for producing single crystal Si films. Usually the thin films formed on amorphous substrates are amorphous or are randomly polycrystalline in the sub-micrometer scale. Therefore, a low temperature process for forming highly crystalline or single crystal layers on temperature sensitive polymeric substrates is needed.

Recently there has also been research to make OLEDs and OLETs from hybrid organic/inorganic materials. However, the research as far as is known to the applicants of this invention, has not made use of eutectics and buffered, textured, substrates for deposition of the inorganic semiconductor material onto the organic polymer layer.

The above-cited references are incorporated by reference as if set forth fully herein.

### OBJECT OF THE INVENTION

It is an object of the present invention to provide a method of producing a hybrid solar cell.

It is yet another object of this invention to provide a method of producing a hybrid solar cell combining a polymer and inorganic material such as, but not limited to, silicon.

It is yet another object of this invention to provide a method of producing a hybrid polymer/inorganic solar cell at low temperature.

It is yet another object of this invention to provide a method of forming crystalline polymer layers on an inexpensive substrate, on which inorganic semiconductor films can then be deposited.

It is yet another object of this invention to provide a method of producing a hybrid solar cell on an inexpensive substrate such as soda-lime glass or metal tape.

It is yet another object of this invention to provide a method of producing a hybrid solar cell from cadmium selenide (CdSe).

It is yet another object of this invention to provide a semiconductor assembly having a substrate, buffer layer, polymer layer.

It is yet another object of this invention to provide a semiconductor film used for either OLETs or OLEDs

### SUMMARY OF INVENTION

The foregoing and other objects can be achieved by depositing inorganic semiconductor films such as silicon from a eutectic alloy melt on an inexpensive substrate such as glass on which a polymer film has been deposited on a textured buffer layer such as MgO or Al203, and all at a temperature below the softening point of glass.

### BRIEF DESCRIPTION OF DRAWINGS

FIG. 1 shows a glass substrate [100] with a textured buffer layer [110].

FIG. 2 shows a glass substrate [200] with a textured buffer layer [210] with a polymer film on top [220] on which a metal thin-film has been deposited [230].

FIG. 3 shows a glass substrate [300] with a textured buffer layer [310] with a polymer film on top [320] on which a metal thin-film has been deposited [330] and finally a eutectic alloy thin film [340] at the very top.

FIG. 4 shows a glass substrate [400] with a textured buffer layer [410] with a polymer film on top [420] on which a thin silicide film has been deposited [430] and finally a eutectic alloy thin film [440] at the very top.

FIG. 5 shows an additional layer 550 being deposited as the top layer to create a triple junction.

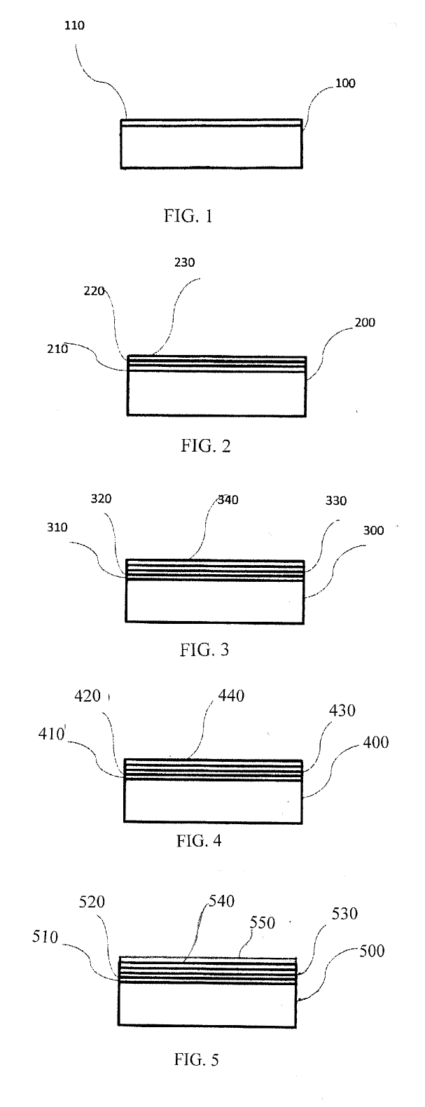

### DETAILED DESCRIPTION OF THE INVENTION

In the present invention, the terms ‘textured’ and ‘large grain’ are defined by the following definitions. The term “textured” means that the crystals in the film have preferential orientation either out-of-plane or in-plane or both. For example, in the present invention the films are highly oriented out-of-plane, along the c-axis.

“Large grain” is defined as a grain size larger than would have been achieved if a silicon (or other inorganic material) had been deposited under the same conditions but without metals, i.e. Cu. Furthermore, “large grain” means the grain size is comparable to or larger than the carrier diffusion length such that electron-hole recombination at grain boundaries is negligible. In semiconductor films this means that the grain size is greater than or equal to the film thickness.

A good high vacuum system with two electron beam guns is used to deposit a metal such as gold and a semiconductor such as silicon, independently. A glass substrate 300 coated with a polymer film 320, preferably textured via buffer layer 310, is held at temperatures between 575 and 600C. These are nominal temperatures. It is understood to one skilled in the art that lower or higher temperatures can also be used depending on the softening temperature of the glass substrate or the reaction kinetics of either gold or silicon with polymer layer. A thin gold film 330 of approximately 10 nm thickness is deposited on the polymer film 320. This is followed by a silicon film 340 deposited at a rate of 2 nm per minute on top of the gold film 330 on polymer 320. The silicon film nucleates heterogeneously or homogenously onto the polymer surface to form the desired film. The film can now be cooled to room temperature, where the film now comprises two phases: gold and a relatively large grained and textured film of silicon/polymer for an inorganic/organic hybrid semiconductor device.

Since a textured polymer buffer layer is desirable, the polymer film can be deposited onto MgO or Al₂O₃ which has in turn been deposited with texture on the glass. The MgO or Al₂O₃ layer serves to align the polymer film such that it is textured.

We have used gold as an example of a metal used in the alloy. However, it is understood that many other metals could be used, for example, Al or Ag or Sn. The same applies to the semiconductor material. For example, instead of silicon one could use germanium of gallium arsenide class of materials. Furthermore, in our example, two electron beam guns serve as an illustrative example. It is understood to one skilled in the art that other methods such as a single gun with multiple hearths, chemical vapor deposition, thermal heating, or sputtering can be used.

The non-crystalline nature of a polymer makes it very difficult to employ a number of existing vapor-liquid and solid phase epitaxial growth processes because such processes rely on the crystalline character of the substrates. The present invention solves this problem because the polymer film is deposited on a textured substrate, such as MgO or Al₂O₃, on glass, thereby replicating the texture of the MgO or Al₂O₃ layers 220. Deposition of the silicon (or other semiconductor material such as germanium) can be performed by methods such as those mentioned above and the polymer will obtain a crystalline, textured, structure. Moreover, the use of a metal such as Au or Al lowers the temperature at which the semiconductor film is deposited onto the polymer coated substrate, thereby further reducing the deposition temperature to as low as 30 degrees Celsius (in the case of the metal gallium and it's eutectic with Si).

Polymers are of two types: natural and synthetic. Natural polymeric materials such as shellac, amber, wool, silk and natural rubber. A variety of other natural polymers exist, such as cellulose, which is the main constituent of wood and paper.

The list of synthetic polymers includes synthetic rubber, phenol formaldehyde resin (or Bakelite), neoprene, nylon, polyvinyl chloride (PVC or vinyl), polystyrene, polyethylene, polypropylene, polyacrylonitrile, PVB, silicone, and many more.

Any of the above mentioned polymers can be applied in this invention.

Deposition of the polymer layer on the textured substrate can take place using a number of the known processes in the art, such as: thermal spray, spin-coating, vapor deposition, CVD, sputter deposition, e-beam evaporation, etc. The deposition technique is adapted to the polymer being deposited. Here we provide one example of a patent illustrating one particular process which enables the deposition of a polymer film on a substrate, and one example of a publication illustrating the same. In both examples the process used is the common e-beam evaporation technique, also used today in the deposition of inorganic semiconductor films such as silicon. And in both examples glass was used as a substrate. A common deposition technique, in this case e-beam, greatly facilitates and simplifies the overall two-material deposition of organic and inorganic films. The examples are: U.S. Pat. No. 3,322,565 A “ Polymer Coatings Through Electron Beam Evaporation” by H. Smith, Jr., and publication “Electron-Beam Deposited Thin Polymer Films: Electrical Properties vs Bombarding Current” by Babcock and Christy.

When making a device such as a solar cell, OLED or OLET in the present invention, a junction is necessary. Junctions in organic materials (molecular photovoltaic materials) require different considerations. In a molecular semiconductor, light generates excitons which may be strongly bound, depending on the strength of the intra-molecular forces compared to those binding the molecules together. In some crystalline organic solids, intermolecular forces are strong and carriers may be considered to occupy bands much like inorganic crystals. In such materials, excitons may be split spontaneously and devices can be designed using similar principles as for inorganic metal-semiconductor junctions.

In other materials, such as amorphous organic solids or polymers, intramolecular forces dominate and the excitons are very tightly bound. In such cases the electrostatic fields available from the difference in work functions of the junction materials is not usually sufficient to split the exciton. Instead, the excitons drift, and only split when they approach the junction with a contact material of different work function. Charge separation thus only occurs at the junction. However, a tightly bound exciton is likely to recombine before it reaches the junction. In addition, in typical molecular materials the exciton diffusion length is a few tens of nanometers. This means that for a Schottky barrier type structure, only the 10 nm of material closest to the junction can contribute to the photocurrent. Hundreds of nm of the material will be needed for a good optical depth. (J. Nelson “The Physics of Solar Cells”, p.137).

The present invention increases the exciton diffusion length by allowing for textured or oriented polymer crystalline film growth and increased grain size. Thus, a p-n heterojunction can be formed between the polymer film and the inorganic film By using a silicide to form a eutectic with the silicon inorganic material, a Schottky barrier can be formed enabling the Schottky barrier type structure, and effecting charge separation.

The textured polymer film and related disclosed here permits a distributed interface that enhances the diffusion length of the polymer film. Some polymer films are known to be conducting, and so provide an advantage when designing a solar cell. Examples of such polymers are P3HT, PEDOT and spiro-OMeTAD. P3HT has excellent electrical properties, a robust structure, and an ease of processing. For OLED device formation according to one aspect of the present invention, a metal cathode and anode such as indium tin oxide (ITO) can be used, where the ITO is deposited on the textured oxide layer (MgO) followed by the other semiconductor layers, and finally the metal (film) cathode for the p-n junction, and metal bus lines on top of this layer for contacts.

### EXAMPLE OF INVENTION

As shown in FIG. 4, a thin polymer film 420, for example P3HT, is deposited on a glass substrate 400 coated with a textured buffer layer 410, MgO, by spin-coating, electron beam evaporation, or any other deposition processes known in the art for polymer film growth. This can be achieved at low temperature, 200° C. Substrate 400 is then heated to between 575 and 600° C. which effectively anneals polymer film 420. These are nominal temperatures. A good high vacuum system with two electron beam guns is used to deposit silicide and silicon independently. It is understood to one skilled in the art that lower or higher temperatures can also be used depending upon the softening temperature of the glass substrate or the reaction kinetics of either the polymer or silicon with the MgO layers when used a substrates. A thin silicide film 430, for example NiSi₂ (nickel silicide), of approximately 10 nm thickness is deposited first. This is followed by a silicon film 440 deposited at a rate of 2 nm per minute on top of the NiSi₂ film. By choosing a silicide rich melt, the silicon film 440 grows epitaxially onto the silicide film 430, which nucleates heterogeneously on the P3HT/MgO surface to form the desired thin film. The film can now be cooled to room temperature, where the film is comprised of two phases: silicide and a relatively large grained and highly textured film of silicon on silicide and textured P3HT/MgO on soda-lime glass. Additionally, a useful Schottky barrier has been formed at the junction of the silicide and the polymer film. In this example, all films—polymer, silicide, and silicon—have improved diffusion length since they have been increased due to the texturing of the films as well as enhancement of grain size. The P3HT layer can serve as a conducting layer in a solar cell or OLED device.

It is also possible, as shown in FIG. 5, to add an additional layer 550 to the previous example—for a triple junction solar cell. A thin polymer film 520 is deposited on a glass substrate 500 coated with a textured buffer layer 510. A silicide film 530 and silicon film 540 are deposited. The additional layer 550 is deposited on the silicon film layer 540. The additional layer 550 may consist of a perovskite material, for example, and instead of using P3HT one could use spiro-OMeTAD as the polymer. A triple junction would increase efficiency. The solar cell can be made by following known processes in the art, such as the formation of a conducting oxide layer, such as indium tin oxide (ITO), for the top contact, along with metal—silver or gold—bus line contacts on the ITO layer.

What is claimed is:

1. A method of providing a junction in a photovoltaic device, comprising the steps of:
coating a glass substrate with a textured buffer layer;
depositing a thin polymer film on the glass substrate;
depositing a silicide film on the polymer film from a silicide-silicon eutectic melt, wherein the polymer film, silicide film, and silicon film replicate the texture from the textured buffer layer, increasing the diffusion lengths of the films.

2. The method of claim 1, wherein forming a Schottky barrier at the polymer/silicide junction.

3. The method of claim 1, wherein the silicide-silicon eutectic melt is silicide rich.

4. The method of claim 1, wherein the diffusion length of the polymer film is greater than 10 nm.

5. The method of claim 1, wherein the diffusion length of the polymer film is greater than 100 nm.

6. The method of claim 1, wherein the polymer film is P3HT.

7. The method of claim 1, wherein the polymer film is PEDOT.

8. The method of claim 1, wherein the polymer film is spiro-OMeTAD.

9. The method of claim 1, wherein the polymer film serves as a conducting layer in a solar cell device.

10. The method of claim 1, wherein depositing said polymer film by spin-coating.

11. The method of claim 1, wherein said junction is used in an OLED device.

12. The method of claim 1, wherein said junction is used in a solar cell device.

13. The method of claim 1, wherein said junction is used in an OLET device.

14. A photovoltaic device comprising:
a glass substrate;
a textured buffer layer deposited on the substrate;
a polymer film deposited on top of the buffer layer, coating the buffer layer with the polymer film;
a silicide film on the polymer film from a silicide-silicon eutectic melt, wherein the polymer film, the silicide film and the silicon film are textured, replicating the texture of the buffer layer, increasing the diffusion lengths of the films, and
a junction, the junction being formed between the polymer film and the silicide film.

15. The photovoltaic device as recited in claim 14, further comprising a Schottky barrier at the junction of the silicide and the polymer film.

16. The photovoltaic device as recited in claim 14, wherein the polymer film is a conducting layer.

17. The photovoltaic device as recited in claim 14, wherein the device is a solar cell, an OLED or an OLET.

18. The photovoltaic device as recited in claim 14, further comprising an additional layer.

19. The photovoltaic device as recited in claim 18, wherein the device is a triple junction solar cell.

20. The photovoltaic device as recited in claim 18 wherein the additional layer is a perovskite.
